(19) United States
(12) Patent Application Publication
(10) Pub. No.: US 2026/0215345 A1
(43) Pub. Date: Jul. 23, 2026

(54) SEMICONDUCTOR PACKAGE

(71) Applicant: Samsung Electronics Co., Ltd., Suwon-si (KR)

(72) Inventors: Jubin Seo, Suwon-si (KR); Junkyoung Lee, Suwon-si (KR); Hojin Lee, Suwon-si (KR)

(21) Appl. No.: 19/451,167

(22) Filed: Jan. 16, 2026

(30) Foreign Application Priority Data
Jan. 21, 2025 (KR) 10-2025-0008853

(51) Int. Cl. H10W 90/20; H10B 80/00; H10D 80/30; H10W 20/00; H10W 20/20; H10W 90/00; H10W 90/28

(52) U.S. Cl. CPC H10W 90/297; H10W 20/215; H10W 90/28; H10W 90/792; H10B 80/00; H10D 80/30; H10W 20/023

(57) ABSTRACT

A semiconductor package includes: a first semiconductor chip including a first semiconductor substrate including a first surface and a second surface opposite thereto, a first through via penetrating the first semiconductor substrate and extending from the first surface to the second surface of the first semiconductor substrate, a first copper alloy seed layer positioned on a side surface of the first through via, a first lower wiring structure positioned on the first surface of the first semiconductor substrate and including a first lower pad, and a first upper wiring structure positioned on the second surface of the first semiconductor substrate and including a first upper pad; and a second semiconductor chip positioned on the first semiconductor chip, wherein a weight ratio of copper included in the first lower pad is higher than a weight ratio of copper included in the first through via.

### CROSS-REFERENCE TO RELATED APPLICATION

This application claims priority under 35 U.S.C. §119 to Korean Patent Application No. 10-2025-0008853, filed on Jan. 21, 2025, in the Korean Intellectual Property Office, the disclosure of which is incorporated by reference herein in its entirety.

### BACKGROUND

With the recent rapid development of the electronics industry and user demands, electronic devices are becoming smaller, more multifunctional, and larger in capacity, requiring highly integrated semiconductor chips. In particular, through-silicon vias (TSVs) are being applied to semiconductor chips to stack them in three dimensions. Research is ongoing to address the decrease in the number of individual elements per unit area included in a semiconductor chip due to the TSVs.

### SUMMARY

Some aspects of the present disclosure provide semiconductor packages having a relatively narrow keep out zones (KOZ) between through-silicon vias (TSVs) and individual elements.

However, the contributions of the present disclosure are not limited to the foregoing, and other contributions will clearly understood by a person having ordinary skill in the relevant technical field from the description below.

According to some implementations of the present disclosure, there is provided a semiconductor package including: a first semiconductor chip including a first semiconductor substrate including a first surface and a second surface opposite thereto, a first through via penetrating the first semiconductor substrate and extending from the first surface to the second surface of the first semiconductor substrate, a first copper alloy seed layer positioned on a side surface of the first through via, a first lower wiring structure positioned on the first surface of the first semiconductor substrate and including a first lower pad, and a first upper wiring structure positioned on the second surface of the first semiconductor substrate and including a first upper pad; and a second semiconductor chip positioned on the first semiconductor chip, wherein the first lower pad and the first through via each include copper, and a weight ratio of copper included in the first lower pad is higher than a weight ratio of copper included in the first through via.

According to some implementations of the present disclosure, there is provided a semiconductor package including: a first semiconductor chip including a first semiconductor substrate including a first surface and a second surface opposite thereto, a first through via penetrating the first semiconductor substrate and extending from the first surface to the second surface of the first semiconductor substrate, a first copper alloy seed layer formed on a side surface of the first through via, a first lower wiring structure positioned on the first surface of the first semiconductor substrate and including a first lower pad and a first lower copper seed layer on a side surface of the first lower pad, and a first upper wiring structure positioned on the second surface of the first semiconductor substrate and including a first upper pad and a first upper copper seed layer on a side surface of the first upper pad; and a second semiconductor chip positioned on the first semiconductor chip and including a second semiconductor substrate including a first surface and a second surface opposite thereto, a second through via penetrating the second semiconductor substrate and extending from the first surface to the second surface of the second semiconductor substrate, a second copper alloy seed layer formed on a side surface of the second through via, a second lower wiring structure positioned on the first surface of the second semiconductor substrate and including a second lower pad and a second lower copper seed layer on a side surface of the second lower pad, and a second upper wiring structure positioned on the second surface of the second semiconductor substrate and including a second upper pad and a second upper copper seed layer on a side surface of the second upper pad, wherein each of the first copper alloy seed layer, the first lower copper seed layer, the second copper alloy seed layer, and the second lower copper seed layer includes copper, a weight ratio of copper in the first copper alloy seed layer is lower than a weight ratio of copper in the first lower copper seed layer, and a weight ratio of copper in the second copper alloy seed layer is lower than a weight ratio of copper in the second lower copper seed layer.

According to some implementations of the present disclosure, there is provided a semiconductor package including: a first semiconductor chip including a first semiconductor substrate including a first surface and a second surface opposite thereto, a first through via penetrating the first semiconductor substrate and extending from the first surface to the second surface of the first semiconductor substrate, a first copper alloy seed layer formed on a side surface of the first through via, a first lower wiring structure positioned on the first surface of the first semiconductor substrate and including a first lower pad and a first lower copper seed layer on a side surface of the first lower pad, and a first upper wiring structure positioned on the second surface of the first semiconductor substrate and including a first upper pad and a first upper copper seed layer on a side surface of the first upper pad; a second semiconductor chip positioned on the first semiconductor chip and including a second semiconductor substrate including a first surface and a second surface opposite thereto, a second through via penetrating the second semiconductor substrate and extending from the first surface to the second surface of the second semiconductor substrate, a second copper alloy seed layer formed on a side surface of the second through via, a second lower wiring structure positioned on the first surface of the second semiconductor substrate and including a second lower pad and a second lower copper seed layer on a side surface of the second lower pad, and a second upper wiring structure positioned on the second surface of the second semiconductor substrate and including a second upper pad and a second upper copper seed layer on a side surface of the second upper pad; and a molding layer which is positioned on the first semiconductor chip and in contact with a side surface of the second semiconductor chip, wherein each of the first copper alloy seed layer, the first through via, the second copper alloy seed layer, and the second through via includes copper and a first metal other than copper, and a weight ratio of the first metal of the first through via is less than a weight ratio of the first metal of the first copper alloy seed layer, and a weight ratio of the first metal of the second through via is less than a weight ratio of the first metal of the second copper alloy seed layer.

### BRIEF DESCRIPTION OF THE DRAWINGS

FIG. 1 is a cross-sectional view of an example of a semiconductor package;

FIG. 2 is a schematic enlarged view of region EX1 of the semiconductor package of FIG. 1;

FIG. 3 is a schematic enlarged view of region EX2 of the semiconductor package of FIG. 1;

FIG. 4 is a graph showing results of a simulation for a change in a volume of through vias in a comparative example and a semiconductor package described herein;

FIG. 5 is a schematic enlarged view illustrating a portion of an example of a semiconductor package; and

FIGS. 6A to 6I are cross-sectional views showing an example of a method of manufacturing a semiconductor package.

### DETAILED DESCRIPTION

In the following description, certain examples are provided. It will be understood that the disclosed examples may be modified in various ways without departing from the scope of this disclosure.

Although terms such as “first,” “second,” “third,” etc. are used throughout this specification to describe various components, parts, regions, layers and/or sections, it should be understood that such components, parts, regions, layers and/or sections are not limited by such terms. Unless the context indicates otherwise, these terms are merely naming conventions used to distinguish one component, part, region, layer or section from another component, part, region, layer or section, without implying any ordering thereof. Thus, a first component, part, region, layer or section discussed in one section of this specification may also be termed a second component, part, region, layer or section in another section of this specification or in a claim without departing from the technical spirit of this disclosure. Additionally, in certain cases, even if the specification does not describe different claimed elements as “first,” “second,” etc., they may be referred to as “first” or “second” in the claims to distinguish them from each other.

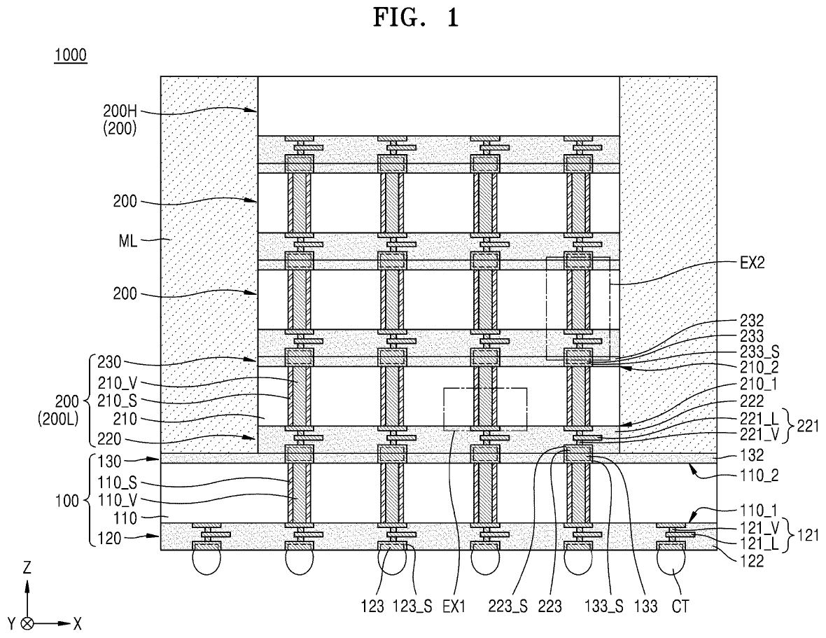

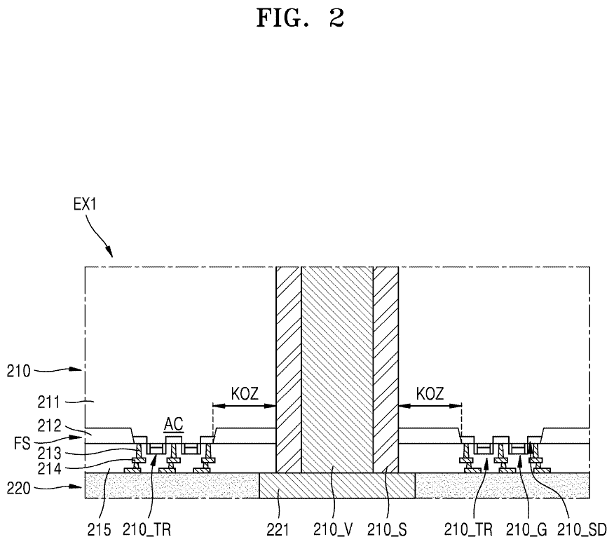

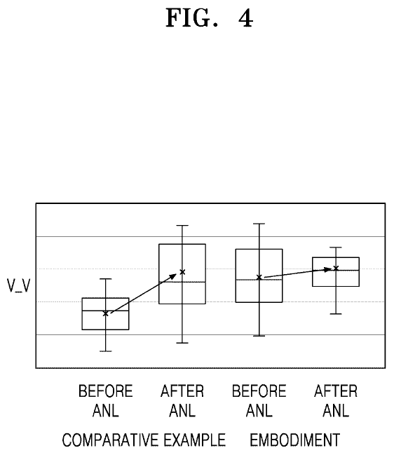

FIG. 1 is a cross-sectional view of an example of a semiconductor package 1000. FIG. 2 is a schematic enlarged view of region EX1 of the semiconductor package 1000 of FIG. 1. FIG. 2 is a schematic enlarged view of region EX2 of the semiconductor package 1000 of FIG. 1. FIG. 4 is a graph showing results of a simulation of a change in a volume V_V of a through via.

In the present specification, unless otherwise specifically defined, a direction parallel to an upper surface of a first semiconductor chip 100 is defined as a first horizontal direction (X direction), a direction perpendicular to the upper surface of the first semiconductor chip 100 is defined as a vertical direction (Z direction), and a direction perpendicular to the first horizontal direction (X direction) and the vertical direction (Z direction) is defined as a second horizontal direction (Y direction). A horizontal direction is defined as a direction that is a composite of the first horizontal direction (Y direction) and the second horizontal direction (X direction).

Referring to FIGS. 1 to 4, the semiconductor package 1000 may include the first semiconductor chip 100, a second semiconductor chip 200 stacked on the first semiconductor chip 100, and a molding layer ML surrounding a side surface of the second semiconductor chip 200.

In some implementations, the first semiconductor chip 100 and the second semiconductor chip 200 may be distinguished from each other based on positions thereof where they are stacked, regardless of the type of semiconductor chip. The first semiconductor chip 100 may refer to a semiconductor chip located in a lower layer among two stacked semiconductor chips, and the second semiconductor chip 200 may refer to a semiconductor chip located in an upper layer among the two stacked semiconductor chips. For example, the first semiconductor chip 100 may be a semiconductor chip located lowermost in the semiconductor package 1000.

In some implementations, the first semiconductor chip 100 may include a serial-parallel conversion circuit and may be a buffer chip for controlling the second semiconductor chip 200, and the second semiconductor chip 200 may be a memory chip including memory cells.

For example, the semiconductor package 1000 including the first semiconductor chip 100 and the second semiconductor chip 200 may be a High Bandwidth Memory (HBM), and the first semiconductor chip 100 may be an HBM controller die and the second semiconductor chip 200 may be a dynamic random-access memory (DRAM) die.

The first semiconductor chip 100 may include a first semiconductor substrate 110, a first through via 110_V, a first copper alloy seed layer 110_S, a first lower wiring structure 120, and a first upper wiring structure 130.

The first semiconductor substrate 110 may include a first surface 110_1 and a second surface 110_2 opposite thereto. The first semiconductor substrate 110 may include a semiconductor material such as silicon (Si, silicon), for example. As another example, the first semiconductor substrate 110 may include a semiconductor material such as germanium (Ge).

The first semiconductor substrate 110 may include a front end of line (FEOL) structure including a plurality of individual elements. For example, the FEOL structure of the first semiconductor substrate 110 may be located at the bottom of the first semiconductor substrate 110. For example, one surface of the FEOL structure may form the first surface 110_1 of the first semiconductor substrate 110. For example, the FEOL structure may be referred to as an active layer of the first semiconductor substrate 110, and the first surface 110_1 of the first semiconductor substrate 110 may be referred to as a front side of the first semiconductor substrate 110.

The plurality of individual elements of the FEOL structure of the first semiconductor substrate 110 may include various microelectronic devices, for example, a metal-oxide-semiconductor field effect transistor (MOSFET) such as a complementary metal-oxide-semiconductor (CMOS) transistor, system large scale integration (LSI), image sensors such as a CMOS imaging sensor (CIS), a micro-electro-mechanical system (MEMS), active elements, passive elements, etc.

The first lower wiring structure 120 may be positioned on the first surface 110_1 of the first semiconductor substrate 110. For example, the first lower wiring structure 120 may be located under the FEOL structure of the first semiconductor substrate 110. For example, the first lower wiring structure 120 may be referred to as a back end of line (BEOL) structure.

The first lower wiring structure 120 may include a first lower wiring pattern 121 and a first lower wiring insulation layer 122 surrounding the first lower wiring pattern 121. The first lower wiring pattern 121 may include a first lower wiring line 121_L extending in the horizontal direction and a first lower wiring via 121_V extending from the first lower wiring line 121_L in the vertical direction (Z direction). The first lower wiring pattern 121 may be electrically connected to the FEOL structure of the first semiconductor substrate 110.

The first lower wiring structure 120 may include a first lower pad 123. The first lower pad 123 may be electrically connected to the first lower wiring pattern 121 and may be surrounded by the first lower wiring insulation layer 122.

In some implementations, the first lower wiring structure 120 may include a first lower copper seed layer 123_S positioned on a side surface and an upper surface of the first lower pad 123. For example, the first lower copper seed layer 123_S may be an element used in forming the first lower pad 123 and may be formed as one body with the first lower pad 123. For example, the first lower copper seed layer 123_S may include copper. A weight ratio of copper in the first lower copper seed layer 123_S may be greater than 99.9 wt %. For example, the first lower copper seed layer 123_S may be a pure copper seed layer.

In some implementations, an external connection terminal CT may be attached to the first lower pad 123. The external connection terminal CT may be configured to electrically and physically connect the semiconductor package 1000 to an external device, such as a printed circuit board, on which the semiconductor package 1000 is mounted. The external connection terminal CT may be formed from, for example, solder balls or solder bumps.

The first upper wiring structure 130 may be positioned on the second surface 110_2 of the first semiconductor substrate 110. For example, the first upper wiring structure 130 may be located on a back side of the first semiconductor substrate 110. For example, the back side of the first semiconductor substrate 110 may be spaced apart from the FEOL structure of the first semiconductor substrate 110. For example, the first upper wiring structure 130 may be referred to as a back-side structure of the first semiconductor substrate 110.

In some implementations, the first upper wiring structure 130 may include a first upper pad 133 and a first upper wiring insulation layer 132 in contact with a side surface of the first upper pad 133. For example, the first upper pad 133 may be located on the second surface 110_2 of the first semiconductor substrate 110 and electrically connected to the first through via 110_V. The side surface of the first upper pad 133 may be surrounded by the first upper wiring insulation layer 132, and an upper surface of the first upper pad 133 may be exposed to the outside of the first upper wiring structure 130.

In some implementations, the first upper wiring structure 130 may further include a first upper wiring pattern (not shown), like the first lower wiring structure 120, and the first upper wiring insulation layer 132 may surround the first upper wiring pattern. The first upper wiring pattern may be positioned between the first upper pad 133 and the first through via 110_V and electrically connect the first upper pad 133 to the first through via 110_V.

In some implementations, the first upper wiring structure 130 may include a first upper copper seed layer 133_S positioned on the side surface and a lower surface of the first upper pad 133. For example, the first upper copper seed layer 133_S may be an element used in forming the first upper pad 133 and may be formed as one body with the first upper pad 133. For example, the first upper copper seed layer 133_S may include copper. A weight ratio of copper in the first upper copper seed layer 133_S may be greater than 99.9 wt %. For example, the first upper copper seed layer 133_S may be a pure copper seed layer.

The first through via 110_V may extend from the first surface 110_1 of the first semiconductor substrate 110 to the second surface 110_2 of the first semiconductor substrate 110. The first through via 110_V may penetrate the first semiconductor substrate 110. The first through via 110_V may be electrically connected to the first lower wiring structure 120 and the first upper wiring structure 130. For example, an electrical signal may travel between the first lower wiring structure 120 and the first upper wiring structure 130 through the first through via 110_V. For example, the first through via 110_V may be in contact with the first lower wiring pattern 121 of the first lower wiring structure 120 and in contact with the first upper pad 133 of the first upper wiring structure 130.

The first copper alloy seed layer 110_S may be located on a side surface of the first through via 110_V. The first copper alloy seed layer 110_S may be between the first through via 110_V and the first semiconductor substrate 110. For example, the first copper alloy seed layer 110_S may be conformally formed on the side surface of the first through via 110_V.

In some implementations, a first barrier layer may be positioned on an outer surface of the first copper alloy seed layer 110_S. For example, the first barrier layer may be between the first copper alloy seed layer 110_S and the first semiconductor substrate 110. The first barrier layer may be conformally formed on the outer surface of the first copper alloy seed layer 110_S. The first barrier layer may prevent a metal material from diffusing into the first semiconductor substrate 110.

In some implementations, an upper surface of the first copper alloy seed layer 110_S may be coplanar with an upper surface of the first through via 110_V. A lower surface of the first copper alloy seed layer 110_S may be coplanar with a lower surface of the first through via 110_V.

In some implementations, the first through via 110_V and the first copper alloy seed layer 110_S may extend into the first lower wiring structure 120. For example, the first through via 110_V and the first copper alloy seed layer 110_S may protrude below the first surface 110_1 of the first semiconductor substrate 110.

The first copper alloy seed layer 110_S may include copper and a first metal other than copper. In some implementations, the first metal may include manganese (Mn), aluminum (Al), titanium (Ti), or silver (Ag). A weight ratio of the first metal of the first copper alloy seed layer 110_S may be less than 1 wt %. For example, the weight ratio of the first metal of the first copper alloy seed layer 110_S may be about 0.2 wt % to about 0.5 wt %. In some implementations, the sum of the weight ratio of the first metal and a weight ratio of copper in the first copper alloy seed layer 110_S may be 100 wt %.

The weight ratio of copper in the first copper alloy seed layer 110_S may be less than the weight ratio of copper in the first upper copper seed layer 133_S. The weight ratio of copper in the first copper alloy seed layer 110_S may be less than the weight ratio of copper in the first lower copper seed layer 123_S. The weight ratio of copper in the first upper copper seed layer 133_S and the weight ratio of copper in the first lower copper seed layer 123_S may be equal to each other.

The first through via 110_V may include copper. In some implementations, during a process of manufacturing the first through via 110_V, the first metal included in the first copper alloy seed layer 110_S may diffuse into the first through via 110_V. Accordingly, the first through via 110_V may also include the first metal.

In some implementations, a weight ratio of the first metal of the first through via 110_V may be less than the weight ratio of the first metal of the first copper alloy seed layer 110_S. A weight ratio of copper in the first through via 110_V may be less than a weight ratio of copper in the first lower pad 123. The weight ratio of copper in the first through via 110_V may be less than a weight ratio of copper in the first upper pad 133.

The second semiconductor chip 200 may be positioned on the first semiconductor chip 100. In some implementations, as illustrated in FIG. 1, the semiconductor package 1000 may include a plurality of second semiconductor chips 200. However, the chip configuration is not limited thereto, and the semiconductor package 1000 may include one first semiconductor chip 100 and one second semiconductor chip 200.

For example, the second semiconductor chip 200 located lowermost among the plurality of second semiconductor chips 200 and in contact with the first semiconductor chip 100 may be referred to as a lowermost second semiconductor chip 200L, and the second semiconductor chip 200 located uppermost among the plurality of second semiconductor chips 200 may be referred to as an uppermost second semiconductor chip 200H.

The second semiconductor chip 200 may include a second semiconductor substrate 210, a second through via 210_V, a second copper alloy seed layer 210_S, a second lower wiring structure 220, and a second upper wiring structure 230. In some implementations, the uppermost second semiconductor chip 200H may not include the second through via 210_V.

The second semiconductor substrate 210 may include a first surface 210_1 and a second surface 210_2 opposite thereto. The second semiconductor substrate 210 may include a semiconductor material such as silicon (Si), for example. As another example, the second semiconductor substrate 210 may include a semiconductor material such as germanium (Ge).

The second semiconductor substrate 210 may include a bare substrate 211 and an FEOL structure FS including a plurality of individual elements. For example, the FEOL structure FS of the second semiconductor substrate 210 may be located below the bare substrate 211 of the second semiconductor substrate 210. For example, one surface of the FEOL structure FS may form the first surface 210_1 of the second semiconductor substrate 210. For example, the FEOL structure FS may be referred to as an active layer of the second semiconductor substrate 210, and the first surface 210_1 of the second semiconductor substrate 210 may be referred to as a front side of the second semiconductor substrate 210.

The FEOL structure FS may include a plurality of transistors 210_TR positioned on the bare substrate 211. An active area AC may be defined by a device isolation film 212 in the bare substrate 211, and the plurality of transistors 210_TR may be formed in the active area AC. The plurality of transistors 210_TR of the FEOL structure FS may include a gate 210_G and a source/drain region 210_SD arranged in a portion of the bare substrate 211 on both sides of the gate 210_G.

The FEOL structure FS may include a plurality of contacts 213 that are connected to the plurality of transistors 210_TR and extend in the vertical direction (Z direction), and a plurality of wiring layers 214 that are connected to the plurality of contacts 213 and extend in the horizontal direction. The FEOL structure FS may further include an interlayer insulating film 215 covering the plurality of contacts 213 and the plurality of wiring layers 214. The plurality of wiring layers 214 may have a multilayer structure including a plurality of metal layers arranged at different vertical levels. The plurality of contacts 213 may electrically connect to each other the plurality of wiring layers 214 arranged at different vertical levels.

Although an FEOL structure has been described based on the FEOL structure FS of the second semiconductor chip 200, an FEOL structure of the first semiconductor chip 100 may also be substantially identical to the FEOL structure FS of the second semiconductor chip 200.

A semiconductor device including various types of transistors and individual elements included in the FEOL structure FS of the second semiconductor substrate 210 may be formed. The second semiconductor chip 200 may include a memory cell. For example, the memory cell may include a non-volatile memory cell such as flash memory, phase-change random-access memory (PRAM), magnetoresistive random-access memory (MRAM), ferroelectric random-access memory (FeRAM), or resistive random-access memory (RRAM). In some implementations, the memory cell may include a volatile memory cell, such as DRAM or static random-access memory (SRAM).

The second lower wiring structure 220 may be positioned on the first surface 210_1 of the second semiconductor substrate 210. For example, the second lower wiring structure 220 may be located below the FEOL structure FS of the second semiconductor substrate 210. For example, the second lower wiring structure 220 may be referred to as a BEOL structure.

The second lower wiring structure 220 may include a second lower wiring pattern 221 and a second lower wiring insulation layer 222 surrounding the second lower wiring pattern 221. The second lower wiring pattern 221 may include a second lower wiring line 221_L extending in the horizontal direction and a second lower wiring via 221_V extending from the second lower wiring line 221_L in the vertical direction (Z direction). The second lower wiring pattern 221 may be electrically connected to the FEOL structure FS of the second semiconductor substrate 210.

The second lower wiring structure 220 may include a second lower pad 223. The second lower pad 223 may be electrically connected to the second lower wiring pattern 221 and surrounded by the second lower wiring insulation layer 222.

In some implementations, the second lower wiring structure 220 may include a second lower copper seed layer 223_S positioned on a side surface and an upper surface of the second lower pad 223. For example, the second lower copper seed layer 223_S may be an element used in forming of the second lower pad 223 and may be formed as one body with the second lower pad 223. For example, the second lower copper seed layer 223_S may include copper. A weight ratio of copper in the second lower copper seed layer 223_S may be greater than 99.9 wt %. For example, the second lower copper seed layer 223_S may be a pure copper seed layer.

The second upper wiring structure 230 may be positioned on the second surface 210_2 of the second semiconductor substrate 210. For example, the second upper wiring structure 230 may be located on a back side of the second semiconductor substrate 210. For example, the back side of the second semiconductor substrate 210 may be spaced apart from the FEOL structure FS of the second semiconductor substrate 210. For example, the second upper wiring structure 230 may be referred to as a back-side structure of the second semiconductor substrate 210.

In some implementations, the second upper wiring structure 230 may include a second upper pad 233 and a second upper wiring insulation layer 232 in contact with a side surface of the second upper pad 233. For example, the second upper pad 233 may be located on the second surface 210_2 of the second semiconductor substrate 210 and electrically connected to the second through via 210_V. The side surface of the second upper pad 233 may be surrounded by the second upper wiring insulation layer 232, and an upper surface of the second upper pad 233 may be exposed to the outside of the second upper wiring structure 230.

In some implementations, the second upper wiring structure 230 may further include a second upper wiring pattern, having characteristics similar to those described for the second lower wiring structure 220, and the second upper wiring insulation layer 232 may surround the second upper wiring pattern. The second upper wiring pattern may be positioned between the second upper pad 233 and the second through via 210_V and electrically connect the second upper pad 233 to the second through via 210_V.

In some implementations, the second upper wiring structure 230 may include a second upper copper seed layer 233_S positioned on the side surface and a lower surface of the second upper pad 233. For example, the second upper copper seed layer 233_S may be an element used in forming the second upper pad 233 and may be formed as one body with the second upper pad 233. For example, the second upper copper seed layer 233_S may include copper. A weight ratio of copper in the second upper copper seed layer 233_S may be greater than 99.9 wt %. For example, the second upper copper seed layer 233_S may be a pure copper seed layer.

The second through via 210_V may extend from the first surface 210_1 of the second semiconductor substrate 210 to the second surface 210_2 of the second semiconductor substrate 210. The second through via 210_V may penetrate the second semiconductor substrate 210.

The second through via 210_V may be electrically connected to the second lower wiring structure 220 and the second upper wiring structure 230. For example, an electrical signal may travel between the second lower wiring structure 220 and the second upper wiring structure 230 through the second through via 210_V. For example, the second through via 210_V may be in contact with the second lower wiring pattern 221 of the second lower wiring structure 220 and in contact with the second upper pad 233 of the second upper wiring structure 230.

The second copper alloy seed layer 210_S may be located on a side surface of the second through via 210_V. The second copper alloy seed layer 210_S may be between the second through via 210_V and the second semiconductor substrate 210. For example, the second copper alloy seed layer 210_S may be conformally formed on the side surface of the second through via 210_V.

In some implementations, an upper surface of the second copper alloy seed layer 210_S may be coplanar with an upper surface of the second through via 210_V. A lower surface of the second copper alloy seed layer 210_S may be coplanar with a lower surface of the second through via 210_V.

In some implementations, a second barrier layer 210_B may be positioned on an outer surface of the second copper alloy seed layer 210_S. For example, the second barrier layer 210_B may be between the second copper alloy seed layer 210_S and the second semiconductor substrate 210. The second barrier layer 210_B may be conformally formed on the outer surface of the second copper alloy seed layer 210_S. The second barrier layer 210_B may prevent a metal material from diffusing into the second semiconductor substrate 210.

In some implementations, the second through via 210_V and the second copper alloy seed layer 210_S may extend into the second lower wiring structure 220. For example, the second through via 210_V and the second copper alloy seed layer 210_S may protrude below the first surface 210_1 of the second semiconductor substrate 210.

The second copper alloy seed layer 210_S may include copper and the first metal other than copper. In some implementations, the first metal may be manganese (Mn). A weight ratio of the first metal of the second copper alloy seed layer 210_S may be less than 1 wt %. For example, the weight ratio of the first metal of the second copper alloy seed layer 210_S may be about 0.2 wt % to about 0.5 wt %. In some implementations, the sum of the weight ratio of the first metal in the second copper alloy seed layer 210_S and a weight ratio of copper in the second copper alloy seed layer 210_S may be 100 wt %. For example, the weight ratio of the first metal of the first copper alloy seed layer 110_S may be substantially the same as the weight ratio of the first metal of the second copper alloy seed layer 210_S.

The weight ratio of copper in the second copper alloy seed layer 210_S may be less than the weight ratio of copper in the second upper copper seed layer 233_S. The weight ratio of copper in the second copper alloy seed layer 210_S may be less than the weight ratio of copper in the second lower copper seed layer 223_S. The weight ratio of copper in the second upper copper seed layer 233_S may be the same as the weight ratio of copper in the second lower copper seed layer 223_S.

The second through via 210_V may include copper. In some implementations, during a process of manufacturing the second through via 210_V, the first metal included in the second copper alloy seed layer 210_S may diffuse into the second through via 210_V. Accordingly, the second through via 210_V may also include the first metal.

In some implementations, a weight ratio of the first metal of the second through via 210_V may be less than the weight ratio of the first metal of the second copper alloy seed layer 210_S. A weight ratio of copper in the second through via 210_V may be less than a weight ratio of copper in the second lower pad 223. The weight ratio of copper in the second through via 210_V may be less than a weight ratio of copper in the second upper pad 233.

As shown in FIG. 2, the second through via 210_V and the transistor 210_TR of the FEOL structure FS of the second semiconductor substrate 210 may be spaced apart from each other. For example, the transistor 210_TR of the FEOL structure FS of the second semiconductor substrate 210 may be affected by the second through via 210_V, which may cause damage to the transistor 210_TR. Thus, the transistor 210_TR may not be formed within a certain distance from the second through via 210_V. An area where the transistors 210_TR cannot be formed around the second through via 210_V may be defined as a keep out zone (KOZ). For example, the greater the KOZ, the less space is available to form the transistor 210_TR.

Referring to FIG. 4, the comparative example is a semiconductor chip in which a through via is formed through a pure copper seed layer, and “embodiment” is a label denoting an example of a semiconductor chip in which a through via is formed through a copper alloy seed layer. The comparative example is a case where when a weight ratio of copper in the seed layer is 99.99 wt %, and the embodiment is a case when a weight ratio of manganese in the seed layer is 0.3 wt %.

In the process of forming a through via, an annealing process ANL is performed, and the volume V_V of the through via is measured. As the volume V_V of the through via changes, pressure (stress) is applied to a substrate through which the through via passes. Accordingly, this affects transistors located around the through via. Thus, the greater the change in the volume V_V of the through via, the greater the pressure that the through via exerts on the substrate, which increases the KOZ where transistors cannot be formed. This reduces the number of transistors that may be formed per unit area. Here, “volume V_V” can denote a dimension corresponding to volume, e.g., width or diameter.

The change in the volume V_V of the through via, which occurs during a process of performing the annealing process ANL on the through via of the embodiment, is smaller than the change in the volume V_V of the through via, which occurs during a process of performing the annealing process ANL on the through via of the comparative example. For example, the change in the volume V_V of the through via of the embodiment may be about 15 % to about 25 % of the change in the volume V_V of the through via of the comparative example.

For example, in the case of the through via of the comparative example, the volume of the through via may increase by 5 angstroms after the annealing process ANL, and in the case of the through via of the embodiment, the volume of the through via may increase by 1 angstrom after the annealing process ANL.

For example, in the process of forming a through via through a copper alloy seed layer including less than 1 wt % of a metal other than copper, the metal other than copper (e.g., manganese) may diffuse into the through via, and thus the change in the volume of the through via may be relatively small.

Accordingly, a semiconductor chip in which a through via is formed through a copper alloy seed layer may have a smaller KOZ and thus include relatively more transistors than a semiconductor chip in which a through via is formed through a pure copper seed layer. In addition, a semiconductor chip including a through via formed through a copper alloy seed layer may have a reduced pressure applied by the through via to a substrate, and thus, semiconductor chip failures may be prevented.

Referring back to FIG. 1, the second semiconductor chip 200 and the first semiconductor chip 100 may be bonded to each other through hybrid bonding. The first upper wiring insulation layer 132 of the first upper wiring structure 130 of the first semiconductor chip 100 may be in contact with the second lower wiring insulation layer 222 of the second lower wiring structure 220 of the second semiconductor chip 200, and the first upper pad 133 of the first upper wiring structure 130 of the first semiconductor chip 100 may be in contact with the second lower pad 223 of the second lower wiring structure 220 of the second semiconductor chip 200.

In some implementations, for example, the second lower pad 223 of the second lower wiring structure 220 of the second semiconductor chip 200 and the first upper pad 133 of the first upper wiring structure 130 of the first semiconductor chip 100 may be diffusion bonded to each other by heat to be one body.

In some implementations, the first upper wiring insulation layer 132 of the first upper wiring structure 130 of the first semiconductor chip 100 and the second lower wiring insulation layer 222 of the second lower wiring structure 220 of the second semiconductor chip 200 may be hydrogen bonded to each other by pressure to be one body.

However, the bonding configuration is not limited thereto, and the first semiconductor chip 100 and the second semiconductor chip 200 may be bonded to each other through a connection terminal, such as a solder bump, through an adhesive film, such as an anisotropic conductive film (ACF), or by a direct bonding method.

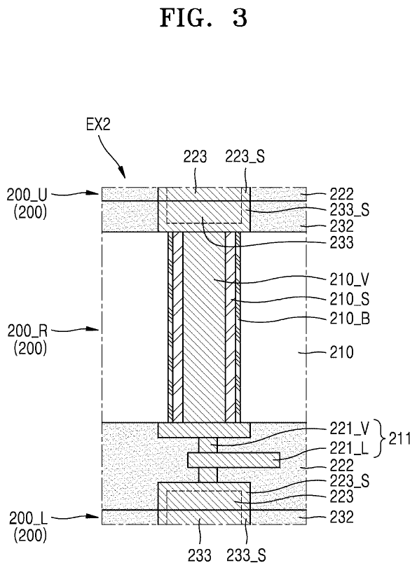

When the semiconductor package 1000 includes the plurality of second semiconductor chips 200, the plurality of second semiconductor chips 200 may be bonded to each other through hybrid bonding. Referring to FIG. 3, the description below is based on a reference second semiconductor chip 200_R, an upper layer second semiconductor chip 200_U located on the reference second semiconductor chip 200_R, and a lower layer second semiconductor chip 200_L located under the reference second semiconductor chip 200_R.

The second upper wiring insulation layer 232 of the second upper wiring structure 230 of the reference second semiconductor chip 200_R may be in contact with the second lower wiring insulation layer 222 of the second lower wiring structure 220 of the upper layer second semiconductor chip 200_U, and the second upper pad 233 of the second upper wiring structure 230 of the reference second semiconductor chip 200_R may be in contact with the second lower pad 223 of the second lower wiring structure 220 of the upper layer second semiconductor chip 200_U.

The second lower wiring insulation layer 222 of the second lower wiring structure 220 of the reference second semiconductor chip 200_R may be in contact with the second upper wiring insulation layer 232 of the second upper wiring structure 230 of the lower layer second semiconductor chip 200_L, and the second lower pad 223 of the second lower wiring structure 220 of the reference second semiconductor chip 200_R may be in contact with the second upper pad 233 of the second upper wiring structure 230 of the lower layer second semiconductor chip 200_L.

However, the bonding configuration is not limited thereto, and the plurality of second semiconductor chips 200 may be bonded to each other through a connection terminal such as a solder bump, through an adhesive film such as an anisotropic conductive film (ACF), or by a direct bonding method.

The molding layer ML may be positioned on the first semiconductor chip 100 and come into contact with the side surface of the second semiconductor chip 200. For example, the molding layer ML may extend along the side surface of the second semiconductor chip 200.

In some implementations, when the width of the first semiconductor chip 100 is the same as the width of the second semiconductor chip 200, the molding layer ML may extend along the side surfaces of the first semiconductor chip 100 and the second semiconductor chip 200. In some implementations, when the width of the first semiconductor chip 100 is greater than the width of the second semiconductor chip 200, the molding layer ML may overlap, in the vertical direction (Z direction), with a portion of the upper surface of the first semiconductor chip 100, the portion not overlapping with the second semiconductor chip 200 in the vertical direction (Z direction).

In some implementations, when the semiconductor package 1000 includes the plurality of second semiconductor chips 200, the molding layer ML may have an upper surface that is coplanar with an upper surface of the uppermost second semiconductor chip 200H. When the width of the first semiconductor chip 100 is greater than the width of the second semiconductor chip 200, an outer surface of the molding layer ML may be aligned vertically with the side surface of the first semiconductor chip 100.

In some implementations, the molding layer ML may include an epoxy resin or a polyimide resin. The molding layer ML may include, for example, an epoxy molding compound (EMC).

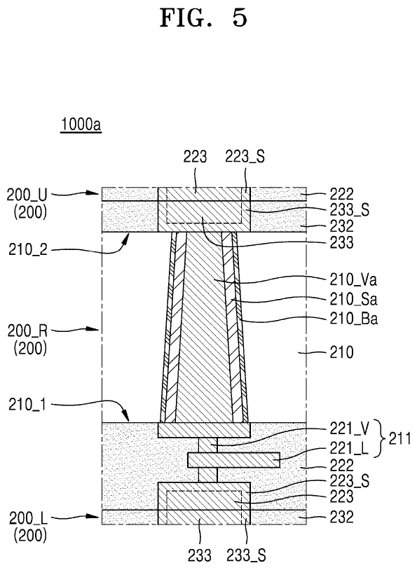

FIG. 5 is a schematic enlarged view illustrating a portion of another example of a semiconductor package 1000a.

Most of the components and materials forming the semiconductor package 1000a described below are substantially the same as or similar to those described above with reference to FIG. 1. Thus, for convenience of description, description will focus on the differences between the semiconductor package 1000a of FIG. 5 and the semiconductor package 1000 of FIG. 1 described above.

FIG. 5 is a schematic enlarged view illustrating a portion corresponding to region EX2 of FIG. 1 of the semiconductor package 1000a.

Referring to FIG. 5, a horizontal width of a second through via 210_Va may vary toward the second surface 210_2 of the second semiconductor substrate 210. For example, the second through via 210_Va may have a horizontal width that is narrower upward in the vertical direction (Z direction). For example, a side surface of the second through via 210_Va may have an inclination greater than 90 degrees with respect to the first surface 210_1 of the second semiconductor substrate 210. For example, the second through via 210_Va may have a tapered shape.

A second copper alloy seed layer 210_Sa may be conformally formed on the side surface of the second through via 210_Va. A second barrier layer 210_Ba may be conformally formed on a side surface of the second copper alloy seed layer 210_Sa. Each of an outer surface of the second copper alloy seed layer 210_Sa and an outer surface of the second barrier layer 210_Ba may have an inclination greater than 90 degrees with respect to the first surface 210_1 of the second semiconductor substrate 210. The second copper alloy seed layer 210_Sa may have characteristics as described for the first copper alloy seed layer 210_S.

In some implementations, the first through via (110_V, see FIG. 1) of the first semiconductor chip (100, see FIG. 1) may have substantially the same shape as the second through via 210_Va of the second semiconductor chip 200.

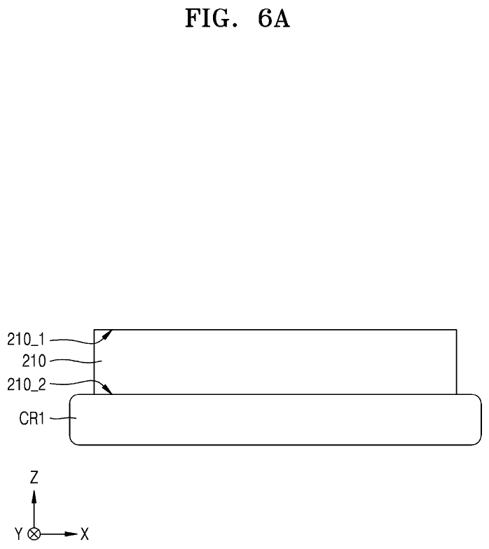

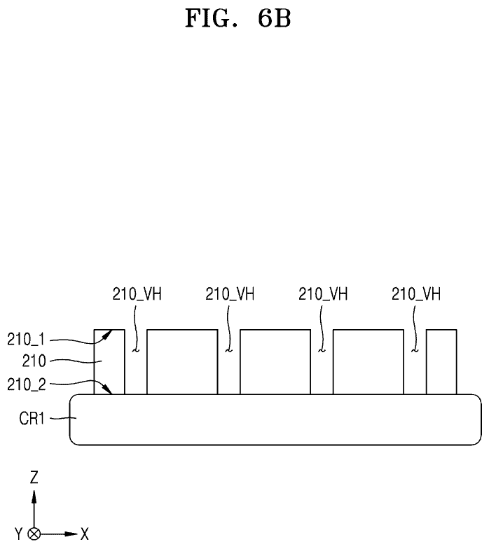

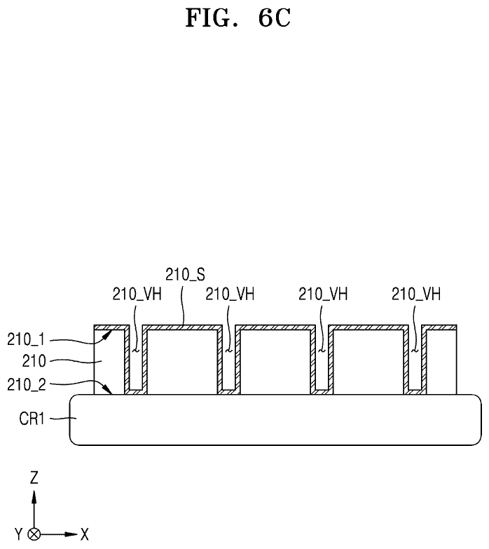

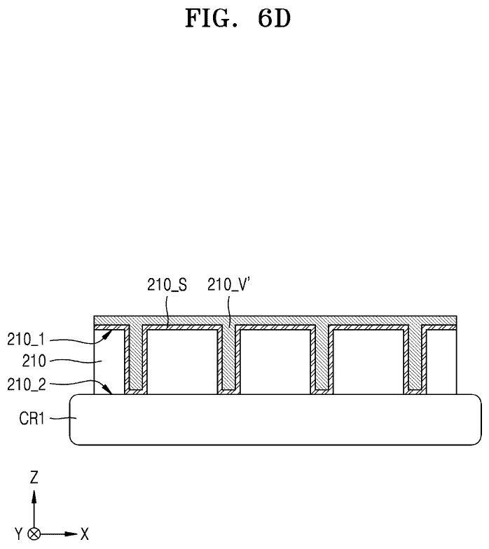

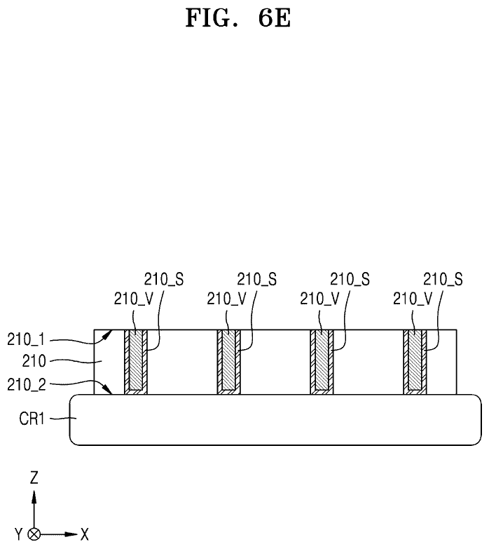

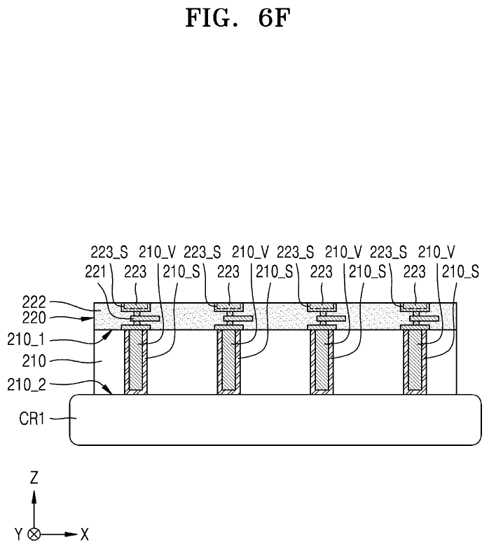

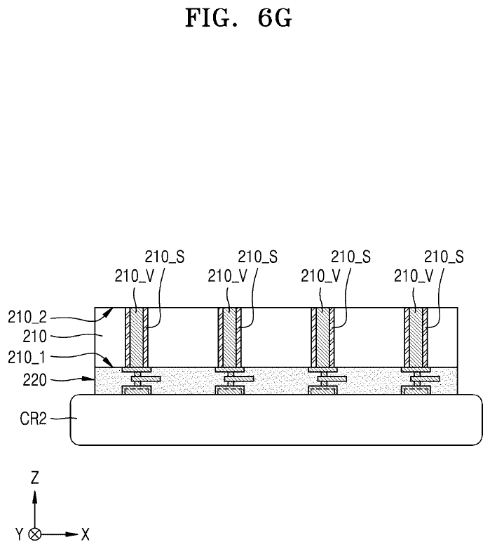

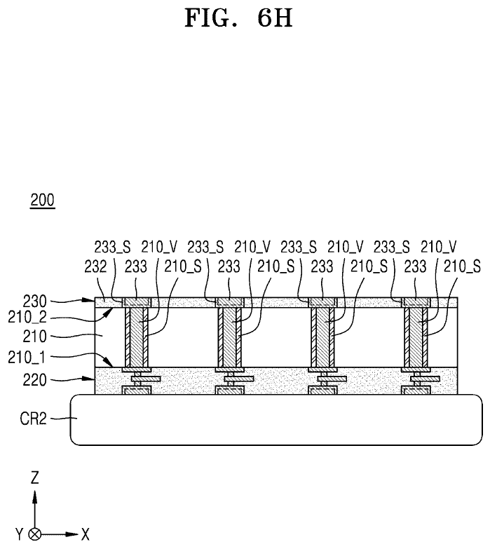

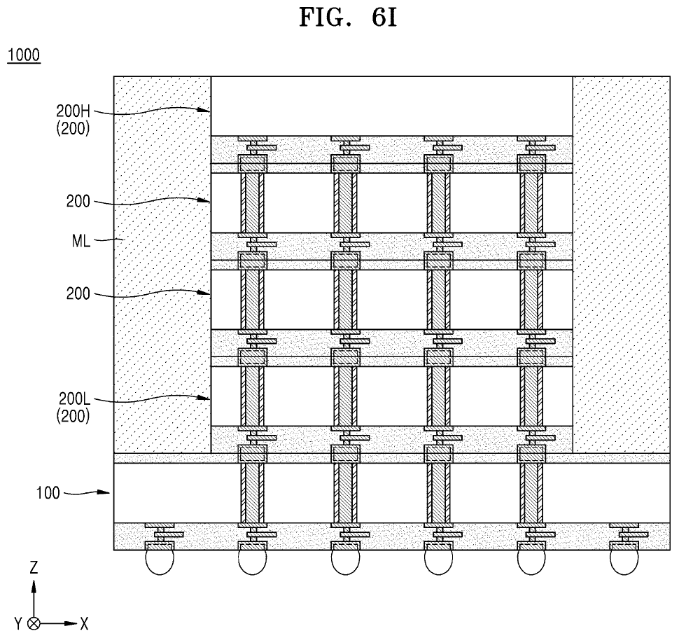

FIGS. 6A to 6I are cross-sectional views illustrating an example of a method of manufacturing a semiconductor package,.

In detail, FIGS. 6A to 6H sequentially illustrate operations of manufacturing the second semiconductor chip 200 by forming the second through via 210_V, the second lower wiring structure 220, and the second upper wiring structure 230 on the second semiconductor substrate 210, and FIG. 6I illustrates the semiconductor package 1000 in which the second semiconductor chips 200 are stacked on the first semiconductor chip 100.

For example, for convenience of description, the description focuses on the second semiconductor chip 200 with reference to FIGS. 6A to 6H, but the process of manufacturing the first semiconductor chip 100 may be substantially the same or similar.

Referring to FIG. 6A, the second semiconductor substrate 210 may be mounted on a first carrier substrate CR1. For example, the second semiconductor substrate 210 may be attached to the first carrier substrate CR1 such that the first surface 210_1 of the second semiconductor substrate 210 faces upward in the vertical direction (Z direction). For example, the second semiconductor substrate 210 may be attached to the first carrier substrate CR1 in a state where up to the FEOL structure (FS, see FIG. 2) is formed. For example, the second semiconductor substrate 210 may be attached to the first carrier substrate CR1 through a die attach film (DAF).

Referring to FIGS. 6B and 6C, a via hole 210_VH extending from the first surface 210_1 to the second surface 210_2 of the second semiconductor substrate 210 may be formed, and the second copper alloy seed layer 210_S may be formed on the first surface 210_1 of the second semiconductor substrate 210 and in the via hole 210_VH.

The via hole 210_VH may completely penetrate the second semiconductor substrate 210. In some implementations, the via hole 210_VH may have a horizontal width that narrows downward in the vertical direction (Z direction). In some implementations, the via hole 210_VH may be formed by performing a dry etching process or a wet etching process. Additionally, in some implementations, the via hole 210_VH may be formed by laser drilling.

The second copper alloy seed layer 210_S may be conformally formed along an inner wall of the via hole 210_VH and the first surface 210_1 of the second semiconductor substrate 210. For example, the second copper alloy seed layer 210_S may also be formed on the DAF corresponding to a bottom surface of the via hole 210_VH. In some implementations, the second barrier layer (210_B, see FIG. 3) may be formed prior to forming of the second copper alloy seed layer 210_S.

In some implementations, the second copper alloy seed layer 210_S may include copper and the first metal other than copper. The first metal may include manganese, titanium, aluminum, or silver. The first metal may be manganese.

A weight ratio of the first metal of the second copper alloy seed layer 210_S may be less than 1 wt %. For example, the weight ratio of the first metal of the first copper alloy seed layer 110_S may be about 0.2 wt % to about 0.5 wt %. In some implementations, the second copper alloy seed layer 210_S may be formed through a sputtering process or a chemical vapor deposition process.

Referring to FIGS. 6D and 6E, the via hole 210_VH may be filled with a copper layer 210_V′ to form the second through via 210_V.

In some implementations, the copper layer 210_V′ may be formed on the second copper alloy seed layer 210_S through an electrolytic plating process, thereby filling the via hole 210_VH with the copper layer 210_V′. Thereafter, a portion of the copper layer 210_V′ and a portion of the second copper alloy seed layer 210_S may be removed to expose the first surface 210_1 of the second semiconductor substrate 210. For example, the portion of the copper layer 210_V′ and the portion of the second copper alloy seed layer 210_S may be removed through a chemical mechanical polishing (CMP) process.

For example, the copper layer 210_V′ from which a portion thereof located on the first surface 210_1 of the second semiconductor substrate 210 has been removed may be referred to as the second through via 210_V.

After forming the copper layer 210_V′ on the second copper alloy seed layer 210_S, an annealing process may be performed. For example, the annealing process may be performed before the CMP process or after the CMP process.

During the annealing process, the first metal included in the second copper alloy seed layer 210_S may diffuse into the copper layer 210_V′ or the second through via 210_V. For example, the weight ratio of the first metal of the second through via 210_V may be less than the weight ratio of the first metal of the second copper alloy seed layer 210_S.

Due to this, after the annealing process, the weight ratio of copper in the copper layer 210_V′ or the second through via 210_V may be reduced. The copper layer 210_V′ and the second through via 210_V, which include the first metal, have relatively small volume changes during the annealing process, and thus the stress applied to the second semiconductor substrate 210 may be relatively small.

Referring to FIG. 6F, the second lower wiring structure 220 may be manufactured on the first surface 210_1 of the second semiconductor substrate 210.

The second lower wiring structure 220 may include the second lower wiring pattern 221 and the second lower wiring insulation layer 222 surrounding the second lower wiring pattern 221. For example, the second lower wiring structure 220 may include the second lower pad 223 and the second lower copper seed layer 223_S positioned on a surface of the second lower pad 223.

The second lower copper seed layer 223_S may include copper. For example, the weight ratio of copper in the second lower copper seed layer 223_S may be greater than 99.9%. For example, the second lower copper seed layer 223_S may be a pure copper seed layer. For example, the weight ratio of copper in the second lower copper seed layer 223_S may be greater than the weight ratio of copper in the second copper alloy seed layer 210_S.

For example, the second lower wiring pattern 221 and the second lower pad 223 may be formed through a damascene process. Before forming the second lower pad 223 by an electrolytic plating process, the second lower copper seed layer 223_S may be formed by a physical vapor deposition method or a chemical vapor deposition method.

For example, in the process of forming the second lower pad 223, the second lower copper seed layer 223_S may be a pure copper layer, and thus a metal other than copper may not diffuse into the second lower pad 223. Thus, the weight ratio of copper in the second lower pad 223 may be higher than the weight ratio of copper in the second through via 210_V.

Referring to FIGS. 6G and 6H, the second upper wiring structure 230 may be formed on the second surface 210_2 of the second semiconductor substrate 210.

A resultant product of FIG. 6F may be separated from the first carrier substrate CR1 and attached to the second carrier substrate CR2 such that the second lower wiring structure 220 faces downward in the vertical direction (Z direction). For example, the second surface 210_2 of the second semiconductor substrate 210 may face upward in the vertical direction (Z direction).

Thereafter, a portion of the second copper alloy seed layer 210_S and a portion of the second semiconductor substrate 210 may be removed so that the second through via 210_V is exposed. For example, through the CMP process, an upper portion of the second copper alloy seed layer 210_S and an upper portion of the second semiconductor substrate 210 may be removed.

Thereafter, the second upper wiring structure 230 may be formed on the second surface 210_2 of the second semiconductor substrate 210. The second upper wiring structure 230 may include the second upper pad 233 and the second upper wiring insulation layer 232 surrounding the second upper pad 233. The second upper pad 233 may overlap the second through via 210_V in the vertical direction (Z direction).

For example, the second upper copper seed layer 233_S may be between the second upper pad 233 and the second upper wiring insulation layer 232. The second upper copper seed layer 233_S may include copper. For example, the weight ratio of copper in the second upper copper seed layer 233_S may be greater than 99.9%.

For example, in the process of forming the second upper pad 233, the second upper copper seed layer 233_S may be a pure copper layer, and thus a metal other than copper may not diffuse into the second upper pad 233. Thus, the weight ratio of copper in the second upper pad 233 may be higher than the weight ratio of copper in the second through via 210_V.

Referring to FIG. 6I together with FIG. 1, the second semiconductor chip 200 may be mounted on the first semiconductor chip 100, and the molding layer ML may be formed to protect the first semiconductor chip 100 and the second semiconductor chip 200.

The first semiconductor chip 100 may be manufactured in substantially the same manner as the method of manufacturing the second semiconductor chip 200 described with reference to FIGS. 6A to 6F. For example, the first copper alloy seed layer 110_S between the first through via 110_V and the first semiconductor substrate 110 of the first semiconductor chip 100 may include copper and the first metal other than copper. For example, the weight ratio of the first metal in the first copper alloy seed layer 110_S may be less than 1 wt %. For example, the weight ratio of the first metal of the first copper alloy seed layer 110_S may be about 0.2 wt % to about 0.5 wt %.

The second semiconductor chip 200 may be bonded to the first semiconductor chip 100 by using a hybrid bonding method. In some implementations, when the semiconductor package 1000 includes the plurality of second semiconductor chips 200, the plurality of second semiconductor chips 200 may be bonded to each other through hybrid bonding.

For example, the second lower wiring structure 220 of the second semiconductor chip 200 may be integrally bonded to the first upper wiring structure 130 of the first semiconductor chip 100. For example, the second lower wiring structure 220 of the second semiconductor chip 200 and the first upper wiring structure 130 of the first semiconductor chip 100 may be collectively referred to as a bonding layer.

For example, the second lower wiring insulation layer 222 of the second lower wiring structure 220 of the second semiconductor chip 200 may be in contact with the first upper wiring insulation layer 132 of the first upper wiring structure 130 of the first semiconductor chip 100 and may be one body through dielectric-dielectric bonding.

For example, the second lower pad 223 of the second lower wiring structure 220 of the second semiconductor chip 200 may be in contact with the first upper pad 133 of the first upper wiring structure 130 of the first semiconductor chip 100 and may be one body through metal-metal bonding.

Thereafter, the molding layer ML may be formed on the first semiconductor chip 100 to cover the second semiconductor chip 200. Afterwards, a portion of the molding layer ML may be removed to expose the upper surface of the second semiconductor chip 200.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While certain examples have been particularly shown and described, it will be understood that various changes in form and details may be made therein without departing from the spirit and scope of this disclosure.

What is claimed is:

1. A semiconductor package comprising:
a first semiconductor chip comprising:
a first semiconductor substrate including a first surface and a second surface opposing one another,
a first through via extending in the first semiconductor substrate from the first surface of the first semiconductor substrate to the second surface of the first semiconductor substrate,
a first copper alloy seed layer on a side surface of the first through via,
a first lower wiring structure on the first surface of the first semiconductor substrate and including a first lower pad, and
a first upper wiring structure on the second surface of the first semiconductor substrate and including a first upper pad; and
a second semiconductor chip on the first semiconductor chip,
wherein the first lower pad and the first through via each comprise copper, and
wherein a weight ratio of copper in the first lower pad is greater than a weight ratio of copper in the first through via.

2. The semiconductor package of claim 1, wherein the first upper wiring structure includes a first upper copper seed layer on a side surface and a lower surface of the first upper pad, wherein the first upper copper seed layer includes copper, and
wherein a weight ratio of copper in the first upper copper seed layer is greater than a weight ratio of copper in the first copper alloy seed layer.

3. The semiconductor package of claim 2, wherein the first lower wiring structure includes a first lower copper seed layer on a side surface and an upper surface of the first lower pad, and
wherein a weight ratio of copper in the first lower copper seed layer is same as the weight ratio of copper in the first upper copper seed layer.

4. The semiconductor package of claim 3, wherein the weight ratio of copper in each of the first lower copper seed layer and the first upper copper seed layer is 99.9 wt % or more.

5. The semiconductor package of claim 1, wherein the first copper alloy seed layer comprises copper and a first metal other than copper, and
wherein a weight ratio of the first metal in the first copper alloy seed layer is in a range from 0.1 wt % to 1 wt %.

6. The semiconductor package of claim 5, wherein the first metal of the first copper alloy seed layer comprises manganese.

7. The semiconductor package of claim 5, wherein the first through via comprises the first metal.

8. The semiconductor package of claim 5, wherein a weight ratio of the first metal in the first through via is less than a weight ratio of the first metal in the first copper alloy seed layer.

9. The semiconductor package of claim 1, wherein the second semiconductor chip comprises:
a second semiconductor substrate including a first surface and a second surface opposing one another,
a second through via extending in the second semiconductor substrate from the first surface of the second semiconductor substrate to the second surface of the second semiconductor substrate,
a second copper alloy seed layer on a side surface of the second through via,
a second lower wiring structure on the first surface of the second semiconductor chip and including a second lower pad, and
a second upper wiring structure positioned on the second surface of the second semiconductor chip and including a second upper pad.

10. The semiconductor package of claim 9, wherein a weight ratio of copper in the second lower pad is higher than a weight ratio of copper in the second through via.

11. The semiconductor package of claim 9, wherein the first upper pad of the first semiconductor chip is in contact with the second lower pad of the second semiconductor chip.

12. A semiconductor package comprising:
a first semiconductor chip comprising:
a first semiconductor substrate including a first surface and a second surface opposing one another,
a first through via extending in the first semiconductor substrate from the first surface of the first semiconductor substrate to the second surface of the first semiconductor substrate,
a first copper alloy seed layer on a side surface of the first through via,
a first lower wiring structure on the first surface of the first semiconductor substrate, wherein the first lower wiring structure includes a first lower pad and a first lower copper seed layer on a side surface of the first lower pad, and
a first upper wiring structure on the second surface of the first semiconductor substrate, wherein the first upper wiring structure includes a first upper pad and a first upper copper seed layer on a side surface of the first upper pad; and
a second semiconductor chip on the first semiconductor chip,
wherein each of the first copper alloy seed layer and the first lower copper seed layer comprises copper, and
a weight ratio of copper in the first copper alloy seed layer is lower than a weight ratio of copper in the first lower copper seed layer.

13. The semiconductor package of claim 12, wherein the first through via comprises copper, and
wherein a weight ratio of copper in the first through via is greater than the weight ratio of copper in the first copper alloy seed layer.

14. The semiconductor package of claim 12, wherein the first copper alloy seed layer comprises manganese, and
wherein a weight ratio of manganese in the first copper alloy seed layer is in a range from 0.2 wt % to 0.5 wt %.

15. The semiconductor package of claim 14, wherein the first through via of the first semiconductor chip comprises manganese.

16. The semiconductor package of claim 15, wherein a weight ratio of manganese in the first through via is less than a weight ratio of manganese in the first copper alloy seed layer.

17. The semiconductor package of claim 12, wherein the first upper pad of the first semiconductor chip is in contact with a second lower pad of the second semiconductor chip.

18. A semiconductor package comprising:
a first semiconductor chip comprising:
a first semiconductor substrate including a first surface and a second surface opposing one another,
a first through via extending in the first semiconductor substrate from the first surface of the first semiconductor substrate to the second surface of the first semiconductor substrate,
a first copper alloy seed layer on a side surface of the first through via,
a first lower wiring structure on the first surface of the first semiconductor substrate, wherein the first lower wiring structure includes a first lower pad and a first lower copper seed layer on a side surface of the first lower pad, and
a first upper wiring structure on the second surface of the first semiconductor substrate, wherein the first upper wiring structure includes a first upper pad and a first upper copper seed layer on a side surface of the first upper pad;
a second semiconductor chip on the first semiconductor chip and comprising:
a second semiconductor substrate including a first surface and a second surface opposing one another,
a second through via extending in the second semiconductor substrate from the first surface of the second semiconductor substrate to the second surface of the second semiconductor substrate,
a second copper alloy seed layer on a side surface of the second through via,
a second lower wiring structure on the first surface of the second semiconductor substrate, wherein the second lower wiring structure includes a second lower pad and a second lower copper seed layer on a side surface of the second lower pad, and
a second upper wiring structure on the second surface of the second semiconductor substrate, wherein the second upper wiring structure includes a second upper pad and a second upper copper seed layer on a side surface of the second upper pad; and
a molding layer on the first semiconductor chip and in contact with a side surface of the second semiconductor chip,
wherein each of the first copper alloy seed layer, the first through via, the second copper alloy seed layer, and the second through via comprises copper and a first metal other than copper,
wherein a weight ratio of the first metal in the first through via is less than a weight ratio of the first metal in the first copper alloy seed layer, and
wherein a weight ratio of the first metal in the second through via is less than a weight ratio of the first metal in the second copper alloy seed layer.

19. The semiconductor package of claim 18, wherein each of the first upper copper seed layer and the second upper copper seed layer comprises copper,
wherein a weight ratio of copper in the first upper copper seed layer and a weight ratio of copper in the second upper copper seed layer are each greater than 99.9 wt %, and
wherein a weight ratio of the first metal in the first copper alloy seed layer and a weight ratio of the first metal in the second copper alloy seed layer are each in a range from 0.2 wt % to 0.5 wt %.

20. The semiconductor package of claim 18, wherein the first upper wiring structure of the first semiconductor chip further includes a first upper wiring insulation layer surrounding the side surface of the first upper pad,
wherein the second lower wiring structure of the second semiconductor chip further includes a second lower wiring insulation layer surrounding the side surface of the second lower pad, and
the first upper wiring insulation layer of the first upper wiring structure of the first semiconductor chip and the second lower wiring insulation layer of the second lower wiring structure of the second semiconductor chip are in contact with each other, and
the first upper pad of the first semiconductor chip is in contact with the second lower pad of the second semiconductor chip.
